(19) United States
(12) Patent Application Publication
(10) Pub. No.: US 2006/0267021 A1
(43) Pub. Date: Nov. 30, 2006

(54) Power devices and methods of manufacture

(75) Inventors: Larry Burton Rowland, Scotia, NY (US); Jody Alan Fronheiser, Selkirk, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/141,605

(22) Filed: May 27, 2005

(51) Int. Cl. H01L 29/15

(52) U.S. Cl. 257/77

(57) ABSTRACT

A power device includes at least one n-type semiconductor layer and at least one p-type silicon carbide epitaxial layer comprising gallium acceptors. Another power device includes at least one epitaxial silicon carbide layer and at least one p-type region formed epitaxially in the epitaxial silicon carbide layer. The p-type region comprises gallium acceptors. A method for forming a semiconductor device includes forming a first conductivity type semiconductor layer on a substrate, forming a second conductivity type semiconductor layer on the first conductivity type semiconductor layer. At least one of the semiconductor layers comprises silicon carbide, and one of the forming steps comprises epitaxially doping the respective silicon carbide layer with gallium acceptors.

### BACKGROUND

The invention relates generally to power devices and, more particularly, to power device structures using gallium as a p-type dopant.

Silicon carbide (SiC) is an attractive alternative to silicon for high voltage, high power applications due to SiC's material properties. For example, SiC's wide band gap and high thermal conductivity facilitate elevated temperature operation, and SiC's high electron mobility enables high-speed switching.

Conventional SiC device structures employ either aluminum or boron as a p-type dopant. However, these conventional p-type dopants have several limitations. For example, use of aluminum during p-type growth typically does not sweep out of the reactor quickly due to its relatively low vapor pressure at the growth temperature (1500 C). Consequently, abrupt changes in doping cannot be achieved for SiC using aluminum as the p-type dopant. Similarly, transitions from heavily doped p-type to lightly doped n-type SiC cannot be achieved without compromising material quality.

Another problem associated with the use of aluminum as a p-type dopant for SiC is step bunching and relatively poor morphology of heavily doped SiC.

It would therefore be desirable to form SiC power devices that avoid the above described limitations caused by the use of conventional aluminum and boron p-type dopants.

### BRIEF DESCRIPTION

Briefly, one aspect of the present invention resides in a power device that includes at least one n-type semiconductor layer and at least one p-type silicon carbide epitaxial layer. The p-type silicon carbide epitaxial layer is doped with gallium acceptors.

Another aspect of the invention resides in a power device that includes at least one epitaxial silicon carbide layer and at least one p-type region formed epitaxially in the epitaxial silicon carbide layer. The p-type region is doped with gallium acceptors.

Yet another aspect of the invention resides in a method for forming a semiconductor device. The method includes forming a first conductivity type semiconductor layer on a substrate and forming a second conductivity type semiconductor layer on the first conductivity type semiconductor layer. At least one of the semiconductor layers comprises silicon carbide, and one of the forming steps comprises epitaxially doping the respective silicon carbide layer with gallium acceptors.

### DRAWINGS

These and other features, aspects, and advantages of the present invention will become better understood when the following detailed description is read with reference to the accompanying drawings in which like characters represent like parts throughout the drawings, wherein:

FIG. 1 depicts an exemplary power device embodiment of the invention;

FIG. 2 illustrates an exemplary p-n-p-n diode embodiment of the invention;

FIG. 3 illustrates an exemplary thyristor embodiment of the invention;

FIG. 4 illustrates a semiconductor-controlled switch embodiment of the invention;

FIG. 5 illustrates an exemplary p-n-p bipolar transistor embodiment of the invention;

FIG. 6 illustrates an exemplary n-p-n bipolar transistor embodiment of the invention;

FIG. 7 depicts another power device embodiment that incorporates a gallium-doped p-type silicon carbide layer as a transition between an aluminum-doped p+ type semiconductor layer and an n-type semiconductor layer;

FIG. 8 illustrates an exemplary lateral metal oxide semiconductor field effect transistor (MOSFET) embodiment of the invention;

FIG. 9 illustrates another exemplary lateral MOSFET embodiment of the invention;

FIG. 10 illustrates an exemplary insulated gate bipolar transistor (IGBT) embodiment of the invention;

FIG. 11 depicts another exemplary IGBT embodiment of the invention;

FIG. 12 illustrates an exemplary vertical DMOS embodiment of the invention; and

FIG. 13 illustrates another exemplary vertical DMOS embodiment of the invention.

### DETAILED DESCRIPTION

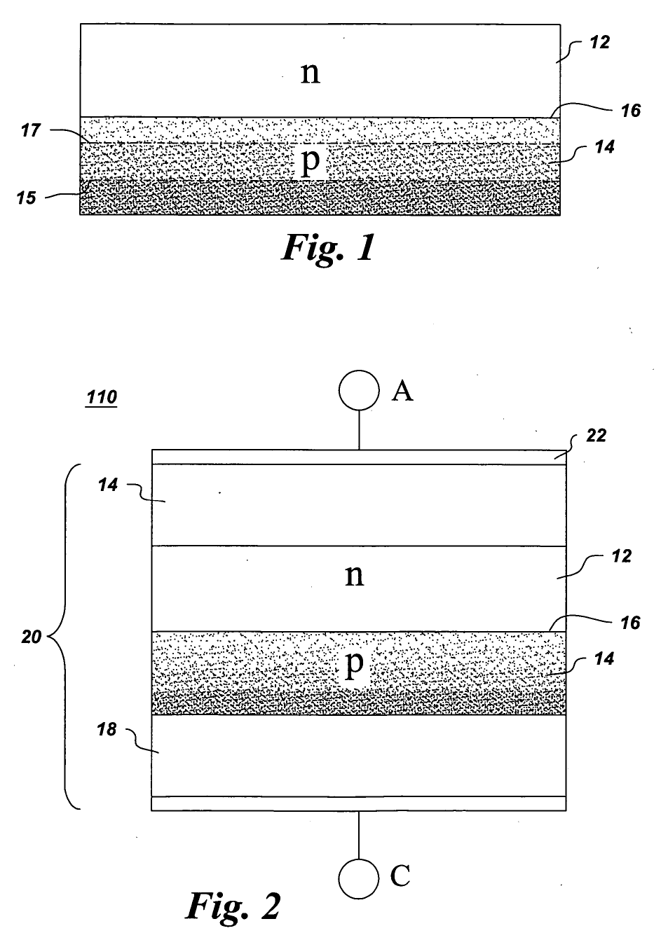

A first set of power device embodiments of the invention are described with reference to FIGS. 1-7. For the exemplary embodiment depicted in FIG. 1, for example, power device 10 includes at least one n-type semiconductor layer 12. Power device 10 further includes at least one p-type silicon carbide epitaxial layer 14 comprising a number of gallium acceptors. As indicated, the n-type semiconductor layer 12 and p-type silicon carbide (SiC) layer 14 define an interface 16, and according to a particular embodiment, the concentration of the gallium acceptors falls by a factor of at least ten within a distance of less than about twenty nanometers (20 nm) of the interface 16. The concentration of gallium acceptors can be determined using secondary ion mass spectrometry (SIMS), for example. As used herein, the term “about” should be understood to indicate plus or minus ten percent (±10%). The concentration of the gallium acceptors is indicated by shading in FIG. 1, where the darker shading corresponds to a higher doping concentration, and the lighter shading indicates a lower concentration of gallium acceptors. It will be understood by those skilled in the art that “n-type” and “p-type” refer to the majority of charge carriers, which are present in a respective layer. For example, in n-type layers, the majority carriers are electrons, and in p-type layers, the majority carriers are holes (the absence of electrons). The n-type layers 12 are typically doped with nitrogen.

Conventional silicon carbide power devices use aluminum acceptor impurities. However, it is difficult to turn aluminum on/off. Accordingly, conventional SiC devices do not have sharp p-n interfaces. Moreover, aluminum is easily oxidized, and aluminum oxide is very stable. Beneficially, the switching properties of gallium are better controlled, due to gallium's higher vapor pressure. More abrupt transitions between p-type and n-type layers limits recombination across interfaces, reduces leakage currents across junctions and permits greater control of device parameters.

Another problem associated with the use of aluminum as a p-type dopant for SiC is step bunching and relatively poor morphology of heavily doped SiC. It is postulated that gallium may alleviate these problems, as well. Although gallium is a slightly deeper dopant (on the order of 320 meV versus about 250 meV for aluminum), the improved turn on/turn off properties associates with gallium may more than offset the lower ionization efficiency.

According to particular embodiments, the n-type semiconductor layer 12 is an n-type silicon carbide epitaxial layer. According to a particular embodiment, the concentration of the gallium acceptors is in a range of about 1×10¹⁶ cm⁻³ to about 1×10¹⁸ cm⁻³ at a first location 15 in the p-type silicon carbide epitaxial layer 14, and the concentration of the gallium acceptors is in a range of about 1×10¹³ cm⁻³ to about 1×10¹⁶ cm⁻³ at a second location 17 in the p-type silicon carbide epitaxial layer 14. More particularly, the concentration of the gallium acceptors is in a range of about 1×10¹⁶ cm⁻³ to about 1×10¹⁸ cm⁻³ within a thickness of about 0.5 to about 5 microns at the first location 15, and the concentration of the gallium acceptors is in a range of about 1×10¹³ cm⁻³ to about 1×10¹⁶ cm⁻³ within a thickness of at least about 1 micron at the second location 17. Locations 15 and 17 are represented by dashed lines in FIG. 1.

For the exemplary embodiment depicted in FIG. 2, for example, power device 110 includes at least two p-type silicon carbide epitaxial layers 14, where at least one of the p-type silicon carbide layers 14 (shown in FIG. 2 as the lower p-type layer) has a number of gallium acceptors. The power device 110 further includes an n-type silicon carbide substrate 18, where the n-type and p-type silicon carbide epitaxial layers 12, 14 are arranged on the n-type silicon carbide substrate 18 in a sequential arrangement alternating between the n-type and p-type layers to form a n-p-n-p stack 20, as indicated in FIG. 2. Power device 110 further includes an anode 22 connected to an upper one of the p-type silicon carbide epitaxial layers 14 and a cathode 24 attached to the n-type silicon carbide substrate 18. For the exemplary embodiment of FIG. 2, the substrate 18, epitaxial layers 12, 14, anode 22 and cathode 24 form a p-n-p-n stack 110. Anode 22 and cathode 24 are typically formed of metal, such as aluminum-titanium multi layers (for the anode) and nickel (cathode), and are configured to be in ohmic contact with the respective semiconductor layers 14, 18.

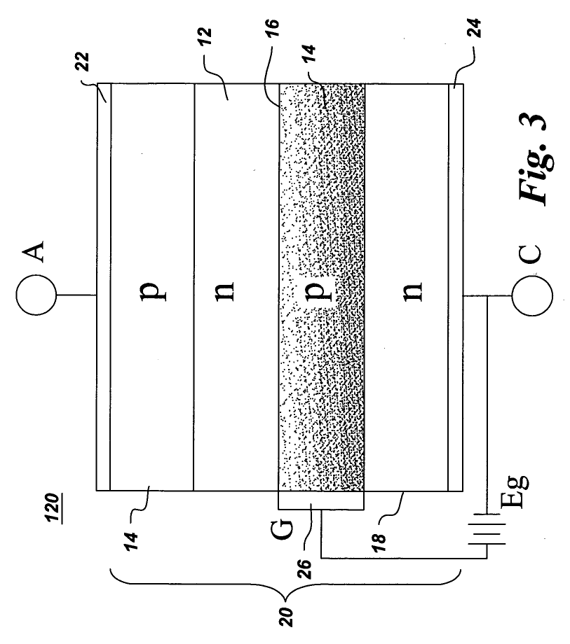

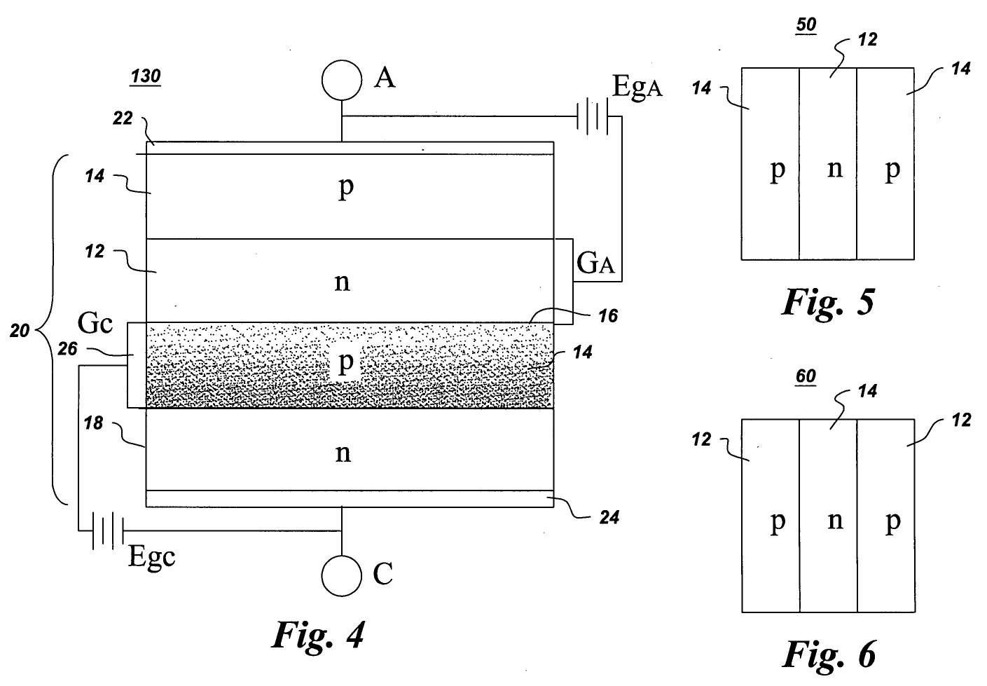

For the exemplary embodiments of FIGS. 3 and 4, the power device further includes at least one gate 26, 27 attached to an intermediate one of the n-type and p-type silicon carbide epitaxial layers 12, 14. For the exemplary embodiment of FIG. 3, a single-gate 26 is attached to the intermediate p-type epitaxial silicon carbide layer 14, and the substrate 18, epitaxial layers 12, 14, anode 22, cathode 24 and gate 26 form a thyristor 120, which is also known as three-terminal semiconductor controlled rectifier 120. The thyristor 120 depicted in FIG. 3 represents one finger of a multi-finger structure that may be formed by laterally connecting a number of thyristors together. Because the thyristor 120 has a four-layered, n-p-n-p structure, the device includes three n-p junctions in series. Operation of the thyristor 120 is as follows. For application of a positive potential to the anode 22 and a negative potential to the cathode 24, no current passes through the thyristor 120, as the middle junction is reversed biased. Application of a sufficiently large (or “breakover”) positive voltage to gate 26 turns the thyristor 120 on. When the applied voltage reaches the breakover voltage, a holding current flows from the cathode 24 to the anode 12 through the three P-N junctions. Once turned on, the gate 26 no longer controls thyristor 120, and current continues to flow until the circuit is switched off or the external voltage is reduced to zero.

FIG. 4 illustrates another embodiment that includes two gate electrodes 26, 27, an anode gate 27 attached to the intermediate n-type layer 12 and a cathode gate 26 attached to the intermediate p-type layer 14. The power device 130 of FIG. 4 is often called a semiconductor-controlled switch 130, and the availability of the second gate electrode provides additional flexibility in circuit design.

According to particular embodiments of FIG. 1, the power device 10 includes one n-type silicon carbide layer 12 and one p-type silicon carbide epitaxial layer 14, and the n-type and p-type silicon carbide layers 12, 14 are configured as one of a P-N and an N-P diode. Beneficially, use of gallium as a p-type dopant provides a more abrupt transition at the p-n interface. This sharper transition produces improved device characteristics, such as reduced leakage currents across the p-n junction.

For the exemplary embodiment of FIG. 5, the power device 50 includes one n-type silicon carbide layer 12 and two p-type silicon carbide epitaxial layers 14. The n-type layer is disposed between the two p-type layers, and the n-type and p-type layers are configured as a p-n-p bipolar transistor 50. Bipolar transistors require relatively sharp transitions between p-type and n-type layers to achieve desirable device characteristics, for example on a length scale of about ten nanometers for certain applications. Beneficially, gallium permits a sharper transition between p-type SiC layers and n-type layers relative to conventional aluminum p-type doping.

For the exemplary embodiment shown in FIG. 6, the power device 60 includes two n-type silicon carbide layers 12 and one p-type silicon carbide epitaxial layer 14. The p-type layer is disposed between the two n-type layers, and the p-type and n-type layers are configured as a n-p-n bipolar transistor 60.

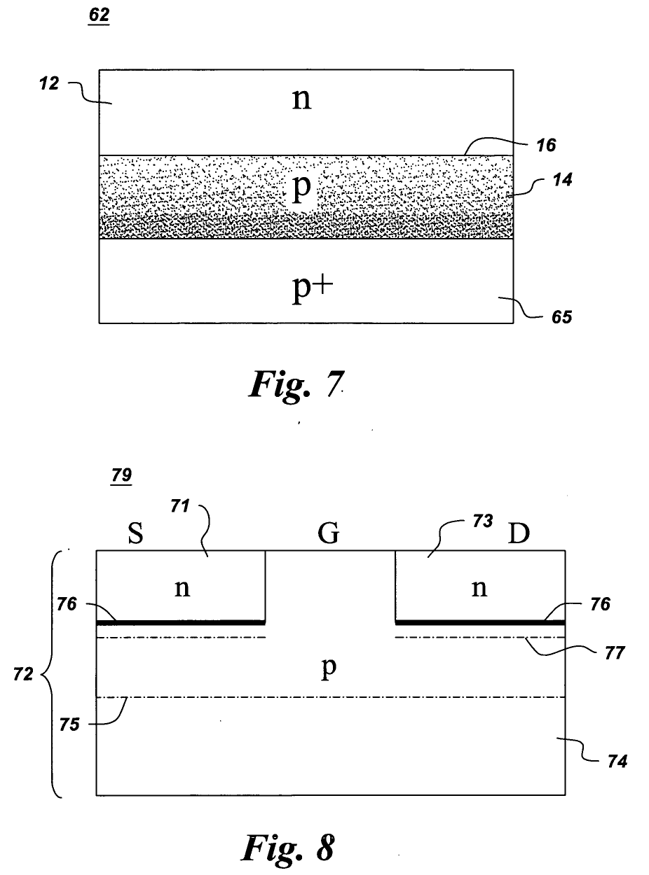

For the exemplary embodiment shown in FIG. 7, the power device 62 further includes a p+-type silicon carbide layer 65 comprising a number of aluminum acceptors. The gallium-doped p-type silicon carbide epitaxial layer 14 is disposed between the p+-type silicon carbide layer 65 and n-type semiconductor layer 12. For the exemplary embodiment depicted in FIG. 7, the gallium-doped p-type silicon carbide epitaxial layer 14 provides a transition between the more heavily doped p+-type silicon carbide layer 65 and the n-type semiconductor layer 12. Beneficially, because gallium is a higher vapor pressure species than aluminum, a more abrupt transition from p-type and n-type material is provided by incorporation of gallium-doped p-type epitaxial layer 14 than would be achieved for a conventional interface between an aluminum doped p-type layer and an n-type layer.

An exemplary method embodiment of the invention will now be described. The method for forming a semiconductor device includes the steps of forming a first conductivity type semiconductor layer on a substrate and forming a second conductivity type semiconductor layer on the first conductivity type semiconductor layer. The first and second conductivity type semiconductor layers define an interface, as discussed above with reference to FIG. 1, for example. At least one of the semiconductor layers comprises silicon carbide, and one of the forming steps includes epitaxially doping the respective silicon carbide layer with gallium acceptors. Doping during epitaxy offers several advantages over technologies such as ion implantation or diffusion. Epitaxial doping does not introduce damage that requires high-temperature annealing unlike ion implantation. Even after the annealing process, properties such as carrier mobility and minority carrier lifetime in ion-implanted material are inferior to those of epitaxial material with the same doping level. Diffusion of a large atom such as gallium in silicon carbide requires sufficient temperatures and times to not be feasible. Additionally, ion implanation and diffusion are only usable in regions near the surface of the semiconductor. In device types such as bipolar transistors and thyristors, epitaxial doping is the only way to introduce acceptor impurities such as gallium far enough from the surface to achieve optimized device characteristics.

According to a particular embodiment, the concentration of the gallium acceptors falls by a factor of at least ten within a distance of less than about twenty nanometers (20 nm) of the interface.

According to a more particular embodiment, the first and second conductivity type semiconductor layers comprise silicon carbide, and the substrate comprises an n-type silicon carbide wafer. For this exemplary embodiment, the first forming step comprises epitaxially growing a p-type silicon carbide layer on the substrate and doping the p-type silicon carbide layer with the gallium acceptors. Similarly, the second forming step comprises epitaxially growing an n-type silicon carbide layer on the p-type silicon carbide layer. According to a particular embodiment, the layers are epitaxially grown using vapor phase epitaxy (VPE), and a liquid gallium source, such as trimeythl gallium, is used for the doping step. Other exemplary epitaxial growth techniques include molecular beam epitaxy (MBE) and sublimation epitaxy. In one example, the silicon carbide layers are epitaxially grown using VPE performed in a temperature range of about 1400-1700 degrees Celsius (for example, at about 1500 degrees Celsius) using silane (SiH₄), propane (C₃H₈) and hydrogen (H₂). Exemplary liquid gallium sources include triethylgallium and trimethylgallium with flowing H₂. The VPE may be performed at reduced or atmospheric pressure, for example in a range of one Torr to about five atmospheres, and more particularly, in a range of about 50 Torr to about 760 Torr. The silicon carbide layers may be epitaxially grown in a variety of polytypes, including, without limitation, 3C, 4H, 6H, 15R, 2H, 8H, 10H, 21R and 27R. According to a particular embodiment the polytype is selected from the group consisting of 4H, 6H, 3C and 15R.

As noted above, gallium has a higher vapor pressure than aluminum or boron. Consequently, gallium has a shorter residence time in the cooler areas of the epitaxial reactor. The shorter residence time provides a more abrupt transition between n-type and p-type SiC and improved dopant control, which in turn facilitates the manufacture of SiC power devices, such as bipolar junction transistors and IGBTs, with improved characteristics. In addition, the resulting devices operate in a more controlled manner because the interfaces between layers have fewer unwanted impurities.

MOSFETS and IGBTs can be formed using the above described method in combination with a regrowth technique. For example, to form the IGBT schematically depicted in FIG. 10, the first forming step comprises epitaxially growing an n-type silicon carbide layer 82 on the substrate. The method further includes etching the n-type silicon carbide layer 82 to form at least one etched region. The second forming step comprises epitaxially growing a p-type silicon carbide layer 74 in the at least one etched region. This technique of etching and re-growing another material in the etched region is termed “re-growth.”

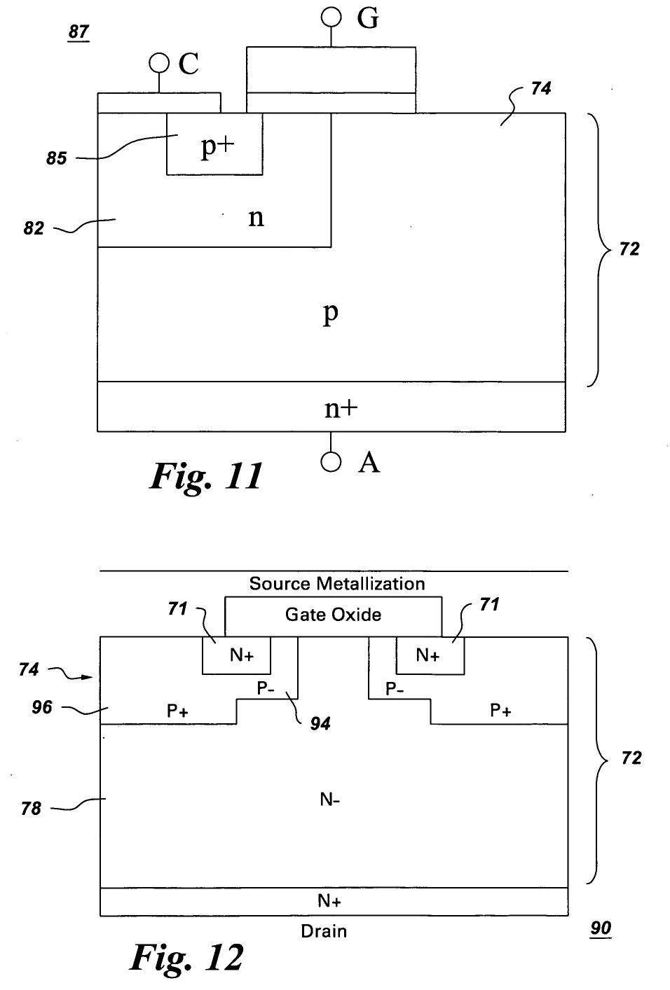

Similarly, to form the IGBT schematically depicted in FIG. 11, the first forming step comprises epitaxially growing a p-type silicon carbide layer 74 on the substrate. The method further includes etching the p-type silicon carbide layer 74 to form at least one etched region. The second forming step comprises epitaxially growing an n-type silicon carbide layer 82 in the at least one etched region. Although this re-growth technique has been described with reference to IGBTs, it is equally applicable to other power devices with doped regions, such as MOSFETs, and the invention will be understood to encompass all such embodiments.

Another set of power device embodiments of the invention is described with reference to FIGS. 8-13. For the exemplary embodiment schematically depicted in FIG. 8, a power device includes at least one epitaxial silicon carbide layer 72 and at least one p-type region 74 formed in the epitaxial silicon carbide layer 72. The p-type region 74 includes a number of gallium acceptors. According to a more particular embodiment, the p-type region 74 defines a boundary 76, and the concentration of gallium acceptors falls by a factor of at least ten within a distance of less than about twenty nanometers (20 nm) of the boundary 76. According to a more particular embodiment, the concentration of the gallium acceptors is in a range of about 1×10¹⁶ cm⁻³ to about 1×10¹⁸ cm⁻³ within a thickness of about 0.5 to about 5 microns at a first location 75 in p-type region 74, and in a range of about 1×10¹³ cm⁻³ to about 1×10¹⁶ cm⁻³ within a thickness of at least about 1 micron at a second location 77 in p-type region 74.

For the exemplary embodiment depicted in FIG. 8, the power device further includes an n-type source region 71 formed in an upper portion of the epitaxial silicon carbide layer 72 and an n-type drain region 73 formed in an upper portion of the epitaxial silicon carbide layer 72. The n-type source and drain regions 71, 73 are in contact with the p-type region 74, and the n-type source region 71, n-type drain region 73 and p-type region 74 form a MOSFET 79. More particularly, the arrangement shown in FIG. 8 is a lateral N-channel MOSFET. Although FIGS. 8, 9, 12 and 13 have rectangular geometries, the p-type and n-type regions may have many geometries, such as rounded, triangular, hexagonal etc. Those skilled in the art will recognize that the invention is not limited by the schematic depictions in FIGS. 8, 9, 12 and 13.

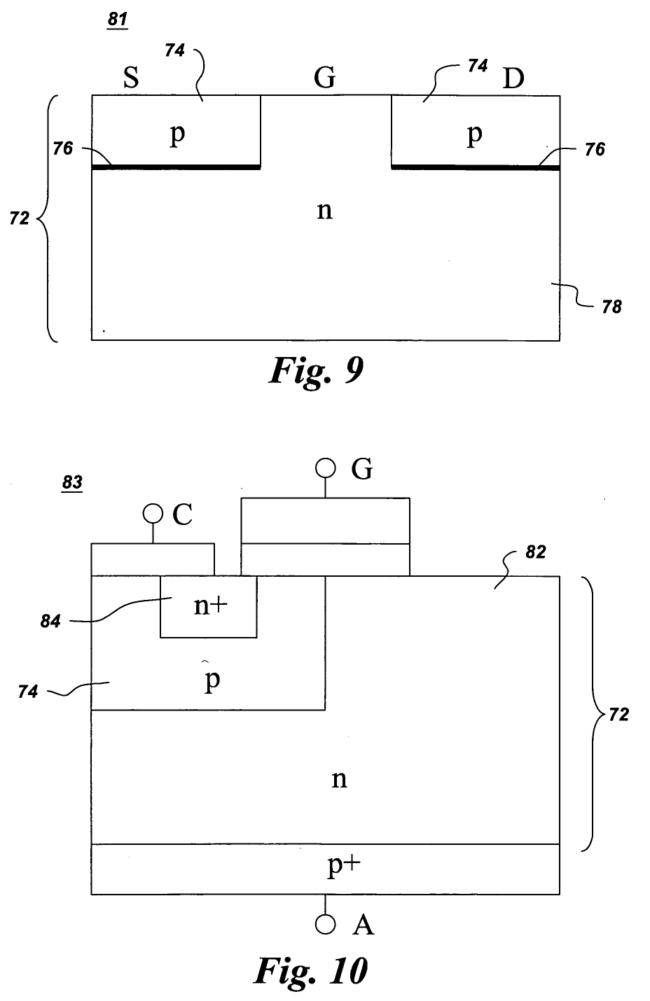

FIG. 9 schematically depicts a lateral P-channel MOSFET embodiment of the invention. For the exemplary embodiment depicted in FIG. 9, the power device includes at least two p-type regions 74 formed in an upper portion of the epitaxial silicon carbide layer 72. A first one of the p-type regions 74 comprises a p-type source region, and a second one of p-type regions 74 comprises a p-type drain region. The power device further includes an n-type region 78 formed in a lower portion of the epitaxial silicon carbide layer 72, and the p-type source and drain regions 74 are in contact with the n-type region. The p-type source region 74, p-type drain region 74 and n-type region 78 are configured to form a lateral P-channel MOSFET 81.

FIG. 12 schematically depicts a vertical N-channel DMOS embodiment of the invention. For the exemplary embodiment shown in FIG. 12, the power device includes at least two p-type regions 74 formed in an upper portion of the epitaxial silicon carbide layer 72. As shown, the power device further includes an n-type region 78 formed in a lower portion of the epitaxial silicon carbide layer 72. At least two n-type source regions 71 are formed in an upper portion of the epitaxial silicon carbide layer 72. Each of the p-type regions 74 is disposed between a respective one of the n-type source regions 71 and the n-type region 78. For the exemplary embodiment schematically shown in FIG. 12, the n-type source regions 71, p-type regions 74 and n-type region 78 are configured to form a vertical n-channel MOSFET 90. For the particular embodiment illustrated in FIG. 12, each of the p-type regions 74 comprises a first region 94 and a second region 96, where the second region 96 has a higher concentration of gallium acceptors than does the first region 94, and the vertical n-channel MOSFET 90 comprises a DMOS structure.

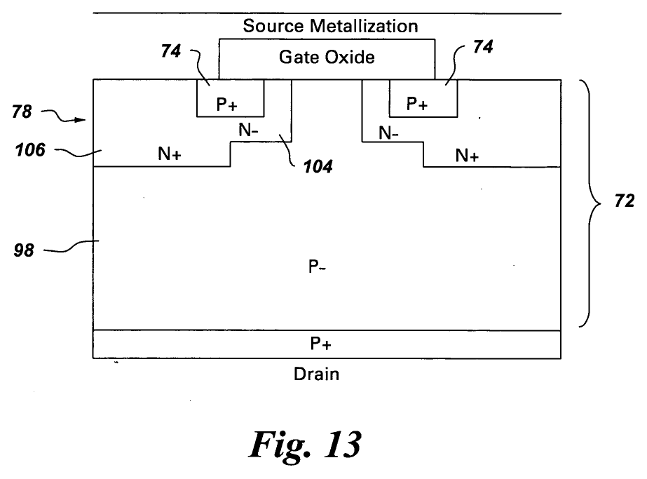

A typical MOSFET comprises a plurality (typically many thousands) of sources connected in parallel. The vertical geometry is desirable, in than it makes possible lower on-state resistances for the same blocking voltage and faster switching than the lateral MOSFET. Many vertical configurations are possible, and, although FIGS. 12 and 13 depict DMOS configurations, the use of gallium as a p-type dopant is equally applicable to other configurations, such as V-groove and U-groove arrangements. The invention encompasses all such vertical MOSFET configurations.

FIG. 13 schematically depicts a vertical P-channel DMOS embodiment of the invention. For the exemplary embodiment shown in FIG. 13, the power device includes at least two p-type source regions 74 formed in an upper portion of the epitaxial silicon carbide layer 72. As shown, the power device further includes at least two n-type regions 78 formed in the epitaxial silicon carbide layer 72 and a p-type lower region 98 formed in a lower portion of the epitaxial silicon carbide layer 72. Each of the n-type regions 78 is disposed between a respective one of the p-type source regions 74 and the p-type lower region 98. The p-type source regions 74, n-type regions 78 and p-type lower region 98 are configured to form a vertical p-channel MOSFET 92. For the particular embodiment illustrated in FIG. 13, each of the n-type regions 78 comprises a first region 104 and a second region 106, where the second region 106 is more heavily doped than is the first region 104, and the vertical p-channel MOSFET 92 comprises a DMOS structure. Although a DMOS configuration is depicted in FIG. 13, the invention is equally applicable to other vertical MOSFET arrangements, including V-groove and U-groove configurations.

FIGS. 10 and 11 schematically depict IGBT embodiments of the invention. For the exemplary embodiment depicted in FIG. 10, the power device includes a first n-type region 82 formed in the epitaxial silicon carbide layer 72 and a second n-type region 84 formed in the epitaxial silicon carbide layer 72. The p-type region 74 is between the first and second n-type regions 82, 84, and the p-type region 74 and first and second n-type regions 82, 84 are configured to form an insulated gate bipolar transistor (IGBT) 83. Beneficially, the use of gallium acceptors permits a sharper transition from p to n type doping than is achievable with conventional aluminum acceptors. This sharper transition provides improved device characteristics for IGBTs.

Another exemplary IGBT embodiment is depicted in FIG. 11. The IGBT of FIG. 11 is similar to that of FIG. 10 but with reversed polarities. In particular, the power device depicted in FIG. 11 further includes an n-type region 82 formed in the epitaxial silicon carbide layer 72. The power device further includes a second p-type region 85 formed in the epitaxial silicon carbide layer 72. As indicated in FIG. 11, for example, the n-type region 82 is between the first and second p-type regions 74, 85. The n-type region 82 and the first and second p-type regions 74, 85 are configured to form an insulated gate bipolar transistor 87, as shown. As discussed above, the first p-type region 74 is formed epitaxially in the epitaxial silicon carbide layer 72 and includes a number of gallium acceptors. According to a particular embodiment, the second p-type region 85 is formed epitaxially in the epitaxial silicon carbide layer 72 and includes a number of gallium acceptors.

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A power device comprising:
at least one n-type semiconductor layer; and
at least one p-type silicon carbide epitaxial layer comprising a plurality of gallium acceptors.

2. The power device of claim 1, wherein said n-type semiconductor layer and said p-type silicon carbide layer define an interface, and wherein a concentration of said gallium acceptors falls by a factor of at least ten within a distance of less than about twenty nanometers (20 nm) of said interface.

3. The power device of claim 1, wherein said n-type semiconductor layer comprises an n-type silicon carbide epitaxial layer.

4. The power device of claim 3, wherein said gallium acceptors have a concentration in a range of about 1×10¹⁶ cm⁻³ to about 1×10¹⁸ cm⁻³ at a first location in said p-type silicon carbide epitaxial layer, and wherein said gallium acceptors have a concentration in a range of about 1×10¹³ cm⁻³ to about 1×10¹⁶ cm⁻³ at a second location in said p-type silicon carbide epitaxial layer.

5. The power device of claim 3, comprising at least two p-type silicon carbide epitaxial layers, wherein at least one of said p-type silicon carbide layers comprises a plurality of gallium acceptors, said power device further comprising:
an n-type silicon carbide substrate, wherein said n-type and p-type silicon carbide epitaxial layers are arranged on said n-type silicon carbide substrate in a sequential arrangement alternating between said n-type and p-type silicon carbide epitaxial layers to form a n-p-n-p stack;
an anode connected to an upper one of said p-type silicon carbide epitaxial layers; and
a cathode attached to said n-type silicon carbide substrate,
wherein said substrate, epitaxial layers, anode and cathode form a semiconductor controlled rectifier.

6. The power device of claim 5, further comprising at least one gate attached to an intermediate one of said n-type and p-type silicon carbide epitaxial layers.

7. The power device of claim 3, comprising one n-type silicon carbide epitaxial layer and one p-type silicon carbide epitaxial layer, and wherein said n-type and p-type silicon carbide epitaxial layers are configured as one of a P-N and an N-P diode.

8. The power device of claim 3, comprising one n-type silicon carbide epitaxial layer and two p-type silicon carbide epitaxial layers, wherein said n-type layer is disposed between said p-type layers, and wherein said n-type and p-type silicon carbide epitaxial layers are configured as a p-n-p bipolar transistor.

9. The power device of claim 3, comprising two n-type silicon carbide layers and one p-type silicon carbide epitaxial layer, wherein said p-type silicon carbide epitaxial layer is disposed between said n-type silicon carbide epitaxial layers, and wherein said p-type and n-type silicon carbide epitaxial layers are configured as a n-p-n bipolar transistor.

10. The power device of claim 1, further comprising a p+-type silicon carbide layer comprising a plurality of aluminum acceptors, wherein said p-type silicon carbide epitaxial layer is disposed between said p+-type silicon carbide layer and said n-type semiconductor layer, and wherein said p-type silicon carbide epitaxial layer provides a transition between said p+-type silicon carbide layer and said n-type semiconductor layer.

11. A power device comprising:
at least one epitaxial silicon carbide layer; and
at least one p-type region formed epitaxially in said epitaxial silicon carbide layer and comprising a plurality of gallium acceptors.

12. The power device of claim 11, wherein said at least one p-type region defines a boundary, and wherein a concentration of said gallium acceptors falls by a factor of at least ten within a distance of less than about twenty nanometers (20 nm) of said boundary.

13. The power device of claim 11, wherein said gallium acceptors have a concentration in a range of about 1×10¹⁶ cm⁻³ to about 1×10¹⁸ cm⁻³ at a first location in said p-type region, and wherein said gallium acceptors have a concentration in a range of about 1×10¹³ cm⁻³ to about 1×10¹⁶ cm⁻³ at a second location in said p-type region.

14. The power device of claim 11, further comprising:
an n-type source region formed in an upper portion of said epitaxial silicon carbide layer; and
an n-type drain region formed in an upper portion of said epitaxial silicon carbide layer;
wherein said n-type source and drain regions are in contact with said p-type region, and wherein said n-type source region, said n-type drain region and said p-type region form a lateral n-channel MOSFET.

15. The power device of claim 11, comprising at least two p-type regions formed in an upper portion of said epitaxial silicon carbide layer, wherein a first one of said p-type regions comprises a p-type source region, and wherein a second one of said p-type regions comprises a p-type drain region, the power device further comprising an n-type region formed in a lower portion of said epitaxial silicon carbide layer, wherein said p-type source and drain regions are in contact with said n-type region, and wherein said p-type source region, said p-type drain region and said n-type region are configured to form a lateral p-channel MOSFET.

16. The power device of claim 11, comprising at least two p-type regions formed in an upper portion of said epitaxial silicon carbide layer, the power device further comprising:
an n-type region formed in a lower portion of said epitaxial silicon carbide layer; and
at least two n-type source regions formed in an upper portion of said epitaxial silicon carbide layer,
wherein each of said p-type regions is disposed between a respective one of said n-type source regions and said n-type region, and wherein said n-type source regions, said p-type regions and said n-type region are configured to form a vertical n-channel MOSFET.

17. The power device of claim 16, wherein each of said p-type regions comprises a first region and a second region, wherein said second region has a higher concentration of gallium acceptors than does said first region, and wherein said vertical n-channel MOSFET comprises a DMOS structure.

18. The power device of claim 11, comprising at least two p-type source regions formed in an upper portion of said epitaxial silicon carbide layer, the power device further comprising:
at least two n-type regions formed in said epitaxial silicon carbide layer; and
a p-type lower region formed in a lower portion of said epitaxial silicon carbide layer,
wherein each of said n-type regions is disposed between a respective one of said p-type source regions and said p-type lower region, and wherein said p-type source regions, said n-type regions and said p-type lower region are configured to form a vertical p-channel MOSFET.

19. The power device of claim 18, wherein each of said n-type regions comprises a first region and a second region, wherein said second region is more heavily doped than is said first region, and wherein said vertical p-channel MOSFET comprises a DMOS structure.

20. The power device of claim 11, further comprising:
a first n-type region formed in said epitaxial silicon carbide layer; and
a second n-type region formed in said epitaxial silicon carbide layer, wherein said p-type region is between said first and second n-type regions, and wherein said p-type region and said first and second n-type regions are configured to form an insulated gate bipolar transistor.

21. The power device of claim 11, further comprising:
an n-type region formed in said epitaxial silicon carbide layer; and
a second p-type region formed in said epitaxial silicon carbide layer, wherein said n-type region is between said first and second p-type regions and wherein said n-type region and said first and second p-type regions are configured to form an insulated gate bipolar transistor.

22. The power device of claim 21, wherein said second p-type region is formed epitaxially in said epitaxial silicon carbide layer and comprises a plurality of gallium acceptors.

23. A method for forming a semiconductor device comprising:
forming a first conductivity type semiconductor layer on a substrate; and
forming a second conductivity type semiconductor layer on the first conductivity type semiconductor layer, wherein at least one of the semiconductor layers comprises silicon carbide, and wherein one of said forming steps comprises epitaxially doping the respective silicon carbide layer with a plurality of gallium acceptors.

24. The method of claim 23, wherein the first and second conductivity type semiconductor layers define an interface, and wherein a concentration of the gallium acceptors falls by a factor of at least ten within a distance of less than about twenty nanometers (20 nm) of the interface.

25. The method of claim 23, wherein the first and second conductivity type semiconductor layers comprise silicon carbide, wherein said substrate comprises an n-type silicon carbide wafer, and wherein said first forming step comprises:
epitaxially growing a p-type silicon carbide layer on the substrate; and
epitaxially doping the p-type silicon carbide layer with the gallium acceptors.

26. The method of claim 25, wherein said second forming step comprises epitaxially growing an n-type silicon carbide layer on the p-type silicon carbide layer.

27. The method of claim 25, wherein said forming steps comprise performing vapor phase epitaxy.

28. The method of claim 27, wherein said epitaxial doping step comprises using trimeythl gallium.

29. The method of claim 23, wherein said first forming step comprises epitaxially growing an n-type silicon carbide layer on the substrate, said method further comprising etching the n-type silicon carbide layer to form at least one etched region, wherein said second forming step comprises epitaxially growing a p-type silicon carbide layer in the at least one etched region.

30. The method of claim 23, wherein said first forming step comprises epitaxially growing a p-type silicon carbide layer on the substrate, said method further comprising etching the p-type silicon carbide layer to form at least one etched region, wherein said second forming step comprises epitaxially growing an n-type silicon carbide layer in the at least one etched region.
